(19) United States
(12) Patent Application Publication
(10) Pub. No.: US 2026/0122953 A1
(43) Pub. Date: Apr. 30, 2026

(54) THREE DIMENSIONAL SEMICONDUCTOR DEVICE AND METHOD OF MANUFACTURING THE SAME

(71) Applicant: SAMSUNG ELECTRONICS CO., LTD., Suwon-si (KR)

(72) Inventors: Jinwoo HAN, Suwon-si (KR); SANG-IL HAN, Suwon-si (KR); Gyuhwan Oh, Suwon-si (KR); Seunguk Han, Suwon-si (KR)

(73) Assignee: SAMSUNG ELECTRONICS CO., LTD., Suwon-si (KR)

(21) Appl. No.: 19/213,381

(22) Filed: May 20, 2025

(30) Foreign Application Priority Data
Oct. 31, 2024 (KR) 10-2024-0152772

(51) Int. Cl. H10D 30/00; H10B 12/00; H10D 1/68; H10D 30/01; H10D 62/60

(52) U.S. Cl. CPC H10D 30/502; H10B 12/315; H10B 12/482; H10B 12/488; H10D 1/714; H10D 62/60; H10B 12/05; H10D 30/0191

(57) ABSTRACT

A three dimensional semiconductor device includes a bit line that is spaced apart from a substrate and extends in a direction perpendicular to a lower surface of the substrate, first semiconductor patterns on a first side surface of the bit line, the first semiconductor patterns including a first uppermost pattern which is an uppermost one of the first semiconductor patterns, and a word line surrounding the first semiconductor patterns. The first uppermost pattern includes a first top edge portion that is spaced apart from a second top edge portion in a first direction, and a first top channel region between the first top edge portion and the second top edge portion, a thickness of the first top edge portion is greater than a thickness of the first top channel region, and a thickness of the second top edge portion is greater than the thickness of the first top channel region.

### CROSS-REFERENCE TO RELATED APPLICATION

This U.S. non-provisional patent application is based on and claims priority under 35 U.S.C. § 119 from Korean Patent Application No. 10-2024-0152772 filed on Oct. 31, 2024, in the Korean Intellectual Property Office, the entire contents of which being hereby incorporated by reference.

### BACKGROUND

The present disclosure relates to a three dimensional semiconductor device and a method of manufacturing the same, and more specifically, relates to a three dimensional semiconductor device with improved reliability and integration.

Semiconductor devices are widely used in the electronics industry because of their small sizes, multi-functional characteristics, and/or low manufacturing costs. Semiconductor devices may be categorized as one of semiconductor memory devices for storing logical data, semiconductor logic devices for processing logical data, and hybrid semiconductor devices having both the function of the semiconductor memory devices and the function of the semiconductor logic devices.

As high-speed and/or low-power electronic devices have been in demand, high-speed and/or low-voltage semiconductor devices used therein have also been in demand, and highly integrated semiconductor devices have been required to satisfy these demands. However, as the integration densities of semiconductor devices increase, electrical characteristics and production yields of the semiconductor devices may be reduced. Thus, techniques for improving electrical characteristics and production yields of semiconductor devices have been variously studied.

### SUMMARY

It is an aspect to provide a three dimensional semiconductor device with improved reliability.

According to an aspect of one or more embodiments, there is provided a three dimensional semiconductor device comprising a bit line that is spaced apart from a substrate and extends in a direction perpendicular to a lower surface of the substrate; first semiconductor patterns on a first side surface of the bit line, the first semiconductor patterns including a first uppermost pattern which is an uppermost one of the first semiconductor patterns; and a word line surrounding the first semiconductor patterns. The first uppermost pattern includes a first top edge portion that is spaced apart from a second top edge portion in a first direction, and a first top channel region between the first top edge portion and the second top edge portion, a thickness of the first top edge portion is greater than a thickness of the first top channel region, and a thickness of the second top edge portion is greater than the thickness of the first top channel region.

According to an aspect of one or more embodiments, there is provided a three dimensional semiconductor device comprising a bit line that is spaced apart from a substrate and extends in a direction perpendicular to a lower surface of the substrate; first semiconductor patterns on a first side surface of the bit line, the first semiconductor patterns including a first uppermost pattern which is an uppermost one of the first semiconductor patterns; second semiconductor patterns on a second side surface of the bit line, the second semiconductor patterns including a second uppermost pattern which is an uppermost one of the second semiconductor patterns; and a word line surrounding the first semiconductor patterns and the second semiconductor patterns. The first uppermost pattern includes a first top edge portion, a first top channel region, and a second top edge portion in sequence in a first direction parallel to the lower surface of the substrate, the second uppermost pattern includes a third top edge portion, a second top channel region, and a fourth top edge portion in sequence in a direction opposite to the first direction, a thickness of the second top edge portion is greater than a thickness of the first top channel region, a thickness of the fourth top edge portion is greater than a thickness of the second top channel region, and one of the first top edge portion and the fourth top edge portion is connected to a precharge line, and the other one of the first top edge portion and the fourth top edge portion is connected to a global bit line.

According to an aspect of one or more embodiments, there is provided a three dimensional semiconductor device comprising a first stacked structure on a substrate and a second stacked structure adjacent to the first stacked structure in a first direction that is parallel to a lower surface of the substrate; and a bit line between the first stacked structure and the second stacked structure. The first stacked structure includes first semiconductor patterns extending in the first direction on the substrate, the first semiconductor patterns including a first uppermost pattern which is an uppermost one of the first semiconductor patterns, the first uppermost pattern including a first top edge portion spaced apart from a second top edge portion in the first direction, and a first top channel region between the first top edge portion and the second top edge portion; a first word line that surrounds the first top channel region and extends in a second direction that is parallel to the lower surface of the substrate and perpendicular to the first direction; and a first data storage pattern on a side surface of the second top edge portion of the first uppermost pattern. The second stacked structure includes second semiconductor patterns extending in the first direction on the substrate, the second semiconductor patterns including a second uppermost pattern which is an uppermost one of the second semiconductor patterns, the second uppermost pattern including a third top edge portion, a fourth top edge portion, and a second top channel region between the third top edge portion and the third top edge portion; a second word line that surrounds the second top channel region and extends in the second direction; and a second data storage pattern on a side surface of the fourth top edge portion of the second uppermost pattern. A thickness of the first top edge portion and a thickness of the second top edge portion are greater than a thickness of the first top channel region, and a thickness of the third top edge portion and a thickness of the fourth top edge portion are greater than a thickness of the second top channel region.

### BRIEF DESCRIPTION OF THE DRAWINGS

Example embodiments will be more clearly understood from the following brief description taken in conjunction with the accompanying drawings representing non-limiting, example embodiments, in which:

FIG. 1 is a schematic circuit diagram illustrating a three dimensional semiconductor device according to some embodiments;

FIGS. 2A, 2B, and 2C are schematic perspective views of a three dimensional semiconductor device according to some embodiments;

FIG. 3A is a perspective view illustrating semiconductor patterns, word lines, bit lines, and data storage patterns of a three dimensional semiconductor device according to some embodiments;

FIG. 3B is a perspective view illustrating semiconductor patterns, word lines, bit lines, data storage patterns, precharge lines, and global bit lines of a three dimensional semiconductor device according to some embodiments;

FIG. 4 is a plan view of a three dimensional semiconductor device according to some embodiments;

FIG. 5A is a cross-sectional view corresponding to a line A-A′ of FIG. 4;

FIG. 5B is a cross-sectional view corresponding to a line B-B′ of FIG. 4;

FIG. 6A is an enlarged view corresponding to a region ‘M’ of FIG. 5A;

FIG. 6B is an enlarged view corresponding to a region ‘N’ of FIG. 5A;

FIGS. 7A, 7B, and 7C are graphs illustrating doping concentrations through an X-ray of FIG. 6A;

FIG. 7D is a view illustrating a plurality of MUX transistors of a three dimensional semiconductor device for illustrating an embodiment;

FIGS. 8A and 8B are enlarged views corresponding to a region ‘M’ of FIG. 5A for illustrating some embodiments;

FIG. 8C is a cross-sectional view corresponding to a line A-A′ of FIG. 4 for illustrating some embodiments;

FIG. 9 to FIG. 18 are drawings illustrating a method of manufacturing a three dimensional semiconductor device according to some embodiments.

### DETAILED DESCRIPTION

Hereinafter, various embodiments will be described with reference to the attached drawings. As used in this specification, a phrase using the form “at least one of A, B, or C” includes within its scope “only A”, “only B”, “only C”, “A and B”, “A and C”, “B and C” and “A, B, and C.”

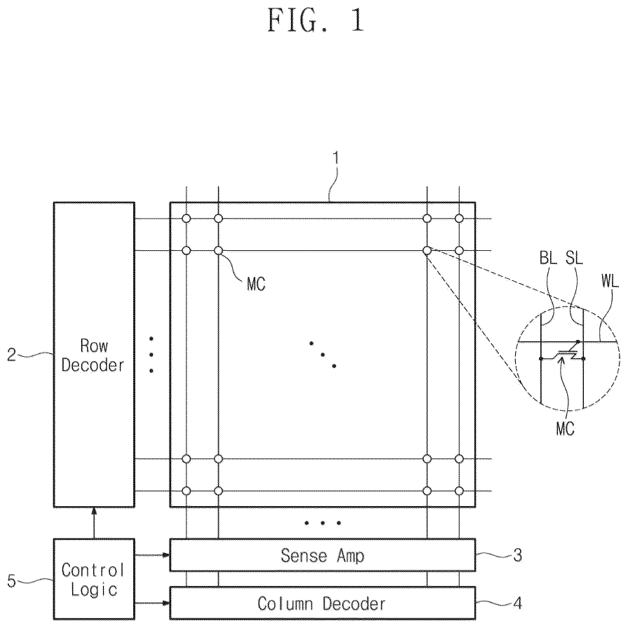

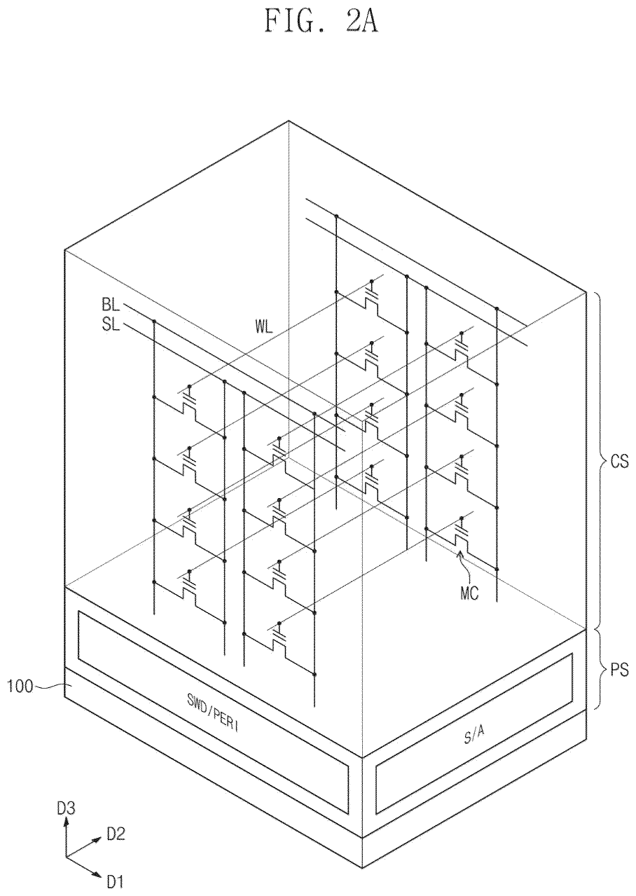

FIG. 1 is a schematic circuit diagram illustrating a three dimensional semiconductor device according to some embodiments.

Referring to FIG. 1, the three dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three dimensionally disposed, and each memory cell MC may be connected to one of the word lines WL, one of the bit lines BL, and one of the source lines SL. In some embodiments, each of the memory cells MC may include one transistor including a memory layer (or a data storing layer).

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of control circuits.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

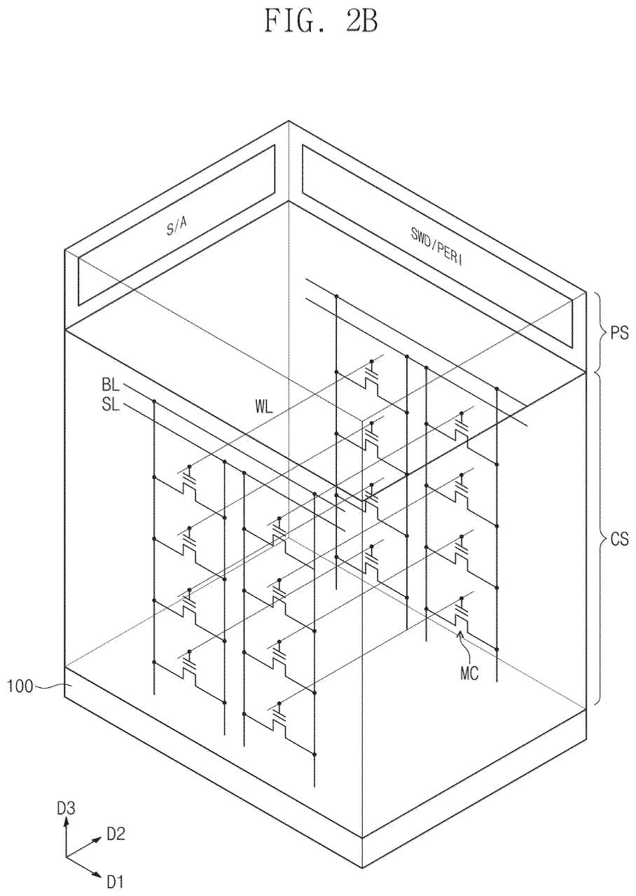

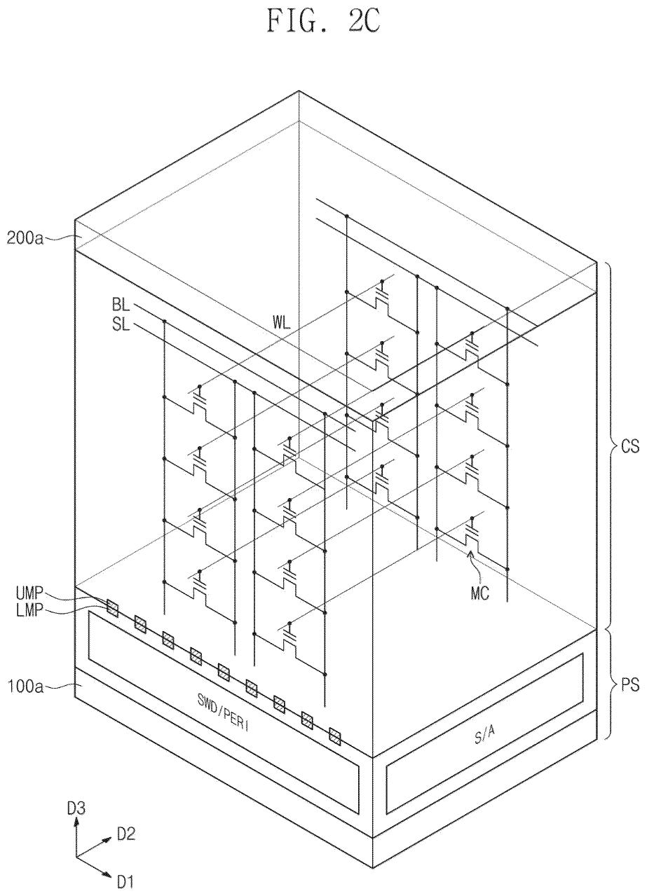

FIGS. 2A, 2B, and 2C are schematic perspective views of a three dimensional semiconductor device according to some embodiments.

Referring to FIG. 2A, a three dimensional semiconductor device may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4 (e.g., FIG. 1), the sense amplifier 3 (e.g., FIG. 1), and the control logic 5 (e.g., FIG. 1) described with reference to FIG. 1.

The substrate 100 may have a plate shape extending along a plane defined by a first direction D1 and a second direction D2. The first direction D1 and the second direction D2 may be parallel to a lower surface of the substrate 100 and may intersect each other. For example, the first direction D1 and the second direction D2 may be horizontal directions that are orthogonal to each other. The peripheral circuit structure PS and the cell array structure CS may be sequentially stacked on the substrate 100 in a third direction D3 that is perpendicular to the lower surface of the substrate 100.

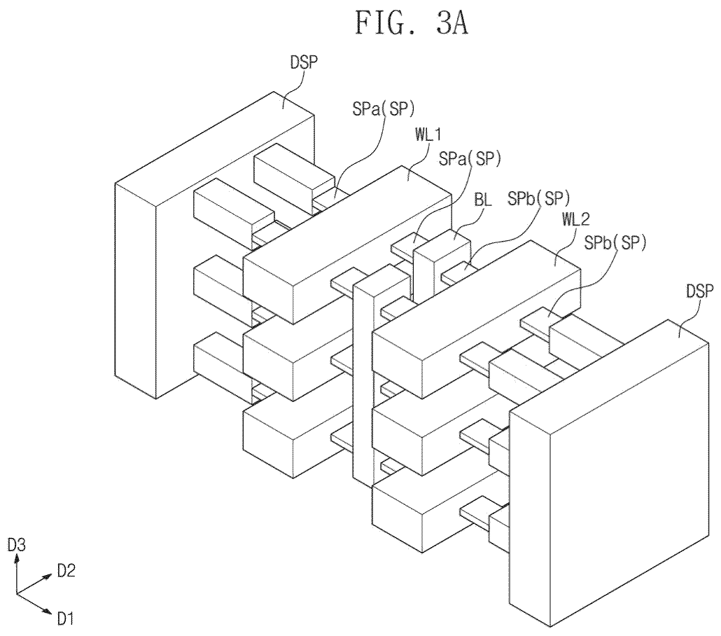

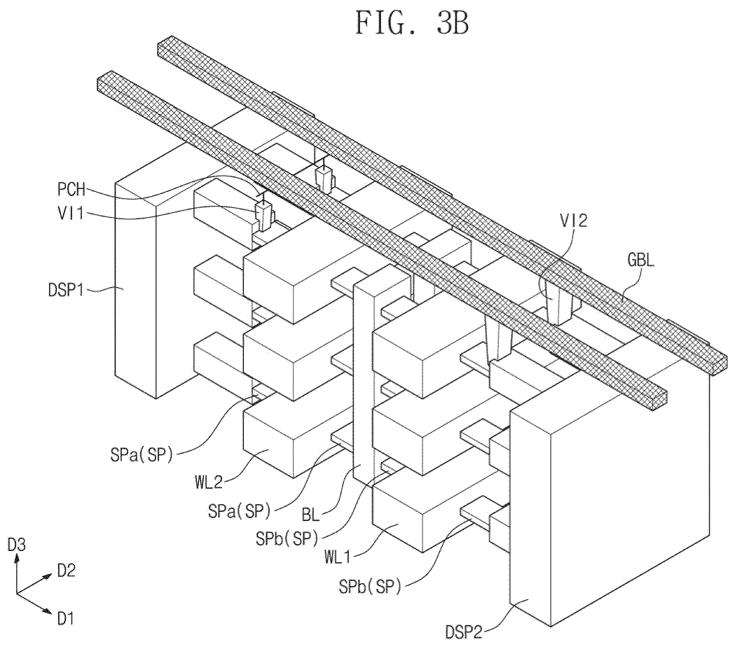

The cell array structure CS may include bit lines BL, source lines SL, and word lines WL, and memory cells MC interposed therebetween. Each of the memory cells MC may be connected to one word line WL, one bit line BL, and one source line SL. In FIGS. 2A, 2B, and 2C, the MUX transistors according to various embodiments described below are omitted for convenience. In FIGS. 2A, 2B, and 2C, the bit lines BL connected together to different memory cells MC arranged in the first direction D1 may correspond to global bit lines GBL described with reference to FIGS. 3A to 7D, and the source lines SL may correspond to plate electrodes PE of data storage patterns DSP2.

Referring to FIG. 2B, a semiconductor device may include a cell array structure CS on a substrate 100 and a peripheral circuit structure PS on the cell array structure CS. The cell array structure CS may be disposed between the substrate 100 and the peripheral circuit structure PS. The peripheral circuit structure PS may include core and peripheral circuits.

Referring to FIG. 2C, a semiconductor device may have a chip to chip (C2C) structure. The peripheral circuit structure PS may include a first substrate 100a. Lower metal pads LMP may be provided at the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and upper metal pads UMP may be provided at the lowermost portion of the cell array structure CS. The upper metal pads UMP may be electrically connected to bit lines BL, source lines SL, and word lines WL. The upper metal pads UMP may be electrically connected to memory cells MC.

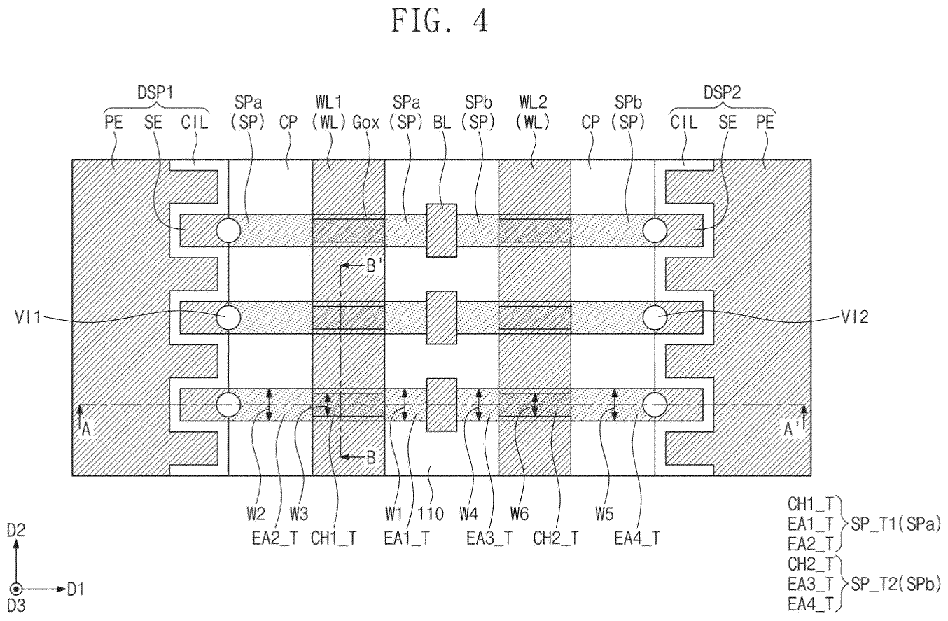

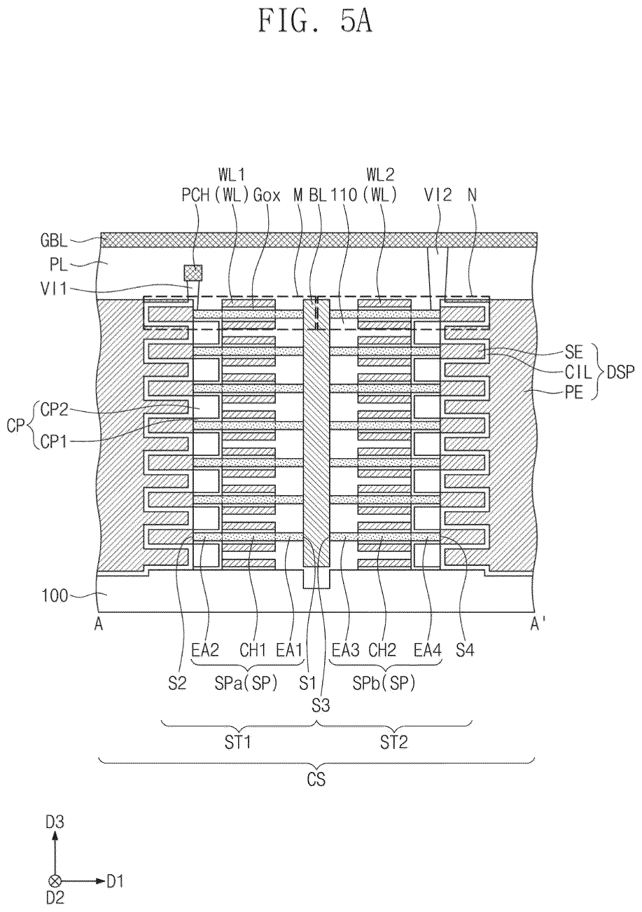

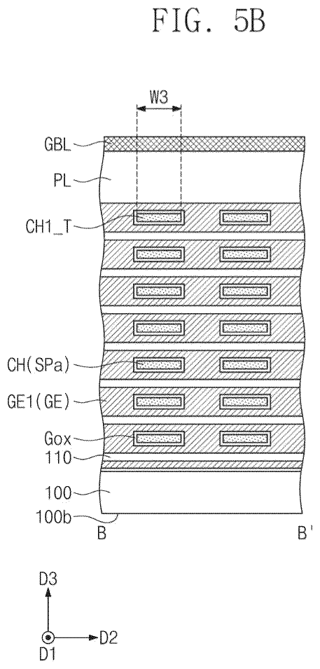

FIG. 3A is a perspective view illustrating semiconductor patterns, word lines, bit lines, and data storage patterns of a three dimensional semiconductor device according to some embodiments. FIG. 3B is a perspective view illustrating semiconductor patterns, word lines, bit lines, data storage patterns, precharge lines, and global bit lines of a three dimensional semiconductor device according to some embodiments. FIG. 4 is a plan view of a three dimensional semiconductor device according to some embodiments. FIG. 5A is a cross-sectional view corresponding to line A-A′ of FIG. 4. FIG. 5B is a cross-sectional view corresponding to line B-B′ of FIG. 4.

Referring to FIGS. 3A to 5B, a three dimensional semiconductor device may include a substrate 100. For example, the substrate 100 may be a semiconductor substrate, an insulator substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may have a plate shape extending along a plane defined by a first direction D1 and a second direction D2. In the present specification, the first direction D1 and the second direction D2 may be directions that are parallel to and intersect a lower surface 100b of the substrate 100. The third direction D3 may be a vertical direction that is perpendicular to the lower surface 100b of the substrate 100. The first to third directions D1, D2, and D3 may be directions that are orthogonal to each other.

A cell array structure CS may be provided on the substrate 100. The cell array structure CS may include a first stacked structure ST1 and a second stacked structure ST2 spaced apart from each other in the first direction D1, and a data storage pattern DSP, which will be described below. For example, although not shown in the drawing, the cell array structure CS may include a plurality of cell array structures CS spaced apart from each other in the first direction D1. Hereinafter, for convenience of explanation, a single cell array structure CS will be described, but the following description may be equally applied to other cell array structures CS.

Each of the first stacked structure ST1 and the second stacked structure ST2 may include semiconductor patterns SP, word lines WL, bit lines BL, first capping patterns CP1, second capping patterns CP2, and a buried insulating pattern 110. For example, the first and second stacked structures ST1 and ST2 may be mirror-symmetrical with respect to the bit lines BT.

The semiconductor pattern SP may extend in the first direction D1 on the substrate 100. The semiconductor pattern SP may be spaced apart from the substrate 100 in the third direction D3. In other words, the semiconductor pattern SP may be floated from the substrate 100. A plurality of semiconductor patterns SP may be provided. The semiconductor patterns SP may be spaced apart from each other in the second direction D2 and the third direction D3. The semiconductor patterns SP spaced apart from each other in the third direction D3 may vertically overlap each other when viewed in a plan view. Sidewalls of the semiconductor patterns SP spaced apart from each other in the third direction D3 may be aligned with each other in the third direction D3.

The semiconductor pattern SP may include a first semiconductor pattern SPa provided in the first stacked structure ST1 and a second semiconductor pattern SPb provided in the second stacked structure ST2. The first semiconductor pattern SPa may be spaced apart from the second semiconductor pattern SPb in the first direction D1. A bit line BL may be provided between the first semiconductor pattern SPa and the second semiconductor pattern SPb.

The first semiconductor pattern SPa may include a first edge portion EA1 and a second edge portion EA2 spaced apart from each other in the first direction D1, and a first channel region CH1 interposed therebetween. The first edge portion EA1, the first channel region CH1, and the second edge portion EA2 may be sequentially disposed in a direction opposite to the first direction D1. The first channel region CH1 may be surrounded by a first word line WL1 described below. The first edge portion EA1 of the first semiconductor pattern SPa may be adjacent to a bit line BL described below. The first edge portion EA1 may be electrically connected to the bit line BL. The second edge portion EA2 may be adjacent to a first data storage pattern DSP1 described below. The second edge portion EA2 may be electrically connected to the first data storage pattern DSP1.

The first semiconductor pattern SPa may have a first side surface S1 and a second side surface S2 that face each other in the first direction D1. The first side surface S1 may be a side surface of the first edge portion EA1, and the second side surface S2 may be a side surface of the second edge portion EA2. The first side surface S1 of the first semiconductor pattern SPa may be adjacent to the bit line BL, and the second side surface S2 may be adjacent to the first data storage pattern DSP1.

The second semiconductor pattern SPb may include a third edge portion EA3 and a fourth edge portion EA4 spaced apart from each other in the first direction D1, and a second channel region CH2 interposed therebetween. The third edge portion EA3, the second channel region CH2, and the fourth edge portion EA4 may be disposed in sequence in the first direction D1. The second channel region CH2 may be surrounded by a second word line WL2 described below. The third edge portion EA3 of the second semiconductor pattern SPb may be adjacent to a bit line BL described below. The third edge portion EA3 may be electrically connected to the bit line BL. The fourth edge portion EA4 may be adjacent to a second data storage pattern DSP2 described below. The fourth edge portion EA4 may be electrically connected to the second data storage pattern DSP2.

The second semiconductor pattern SPb may have a third side surface S3 and a fourth side surface S4 facing each other in the first direction D1. The third side surface S3 may be a side surface of the third edge portion EA3, and the fourth side surface S4 may be a side surface of the fourth edge portion EA4. The third side surface S3 of the second semiconductor pattern SPb may be adjacent to the bit line BL, and the fourth side surface S4 may be adjacent to the second data storage pattern DSP2.

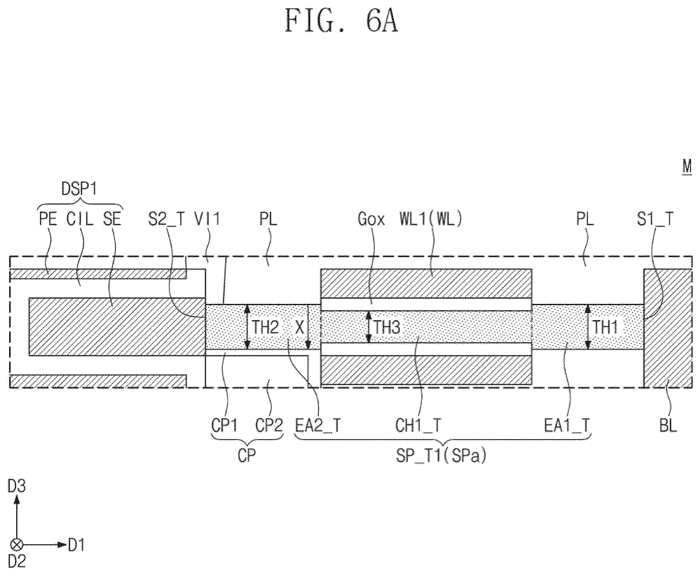

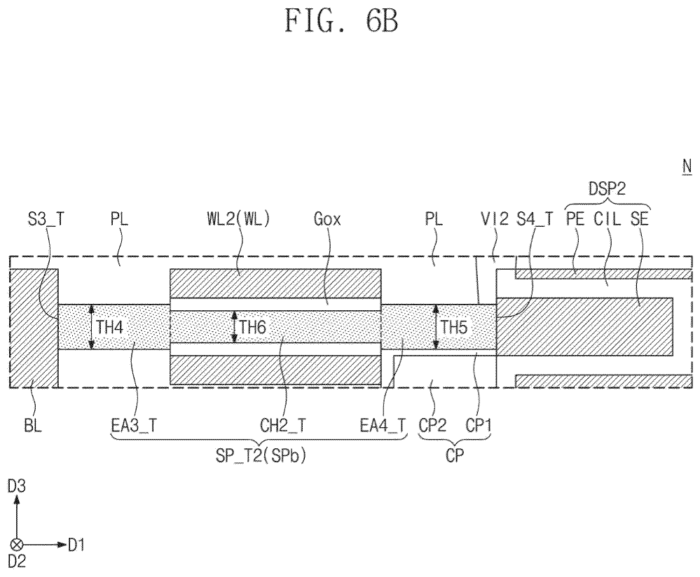

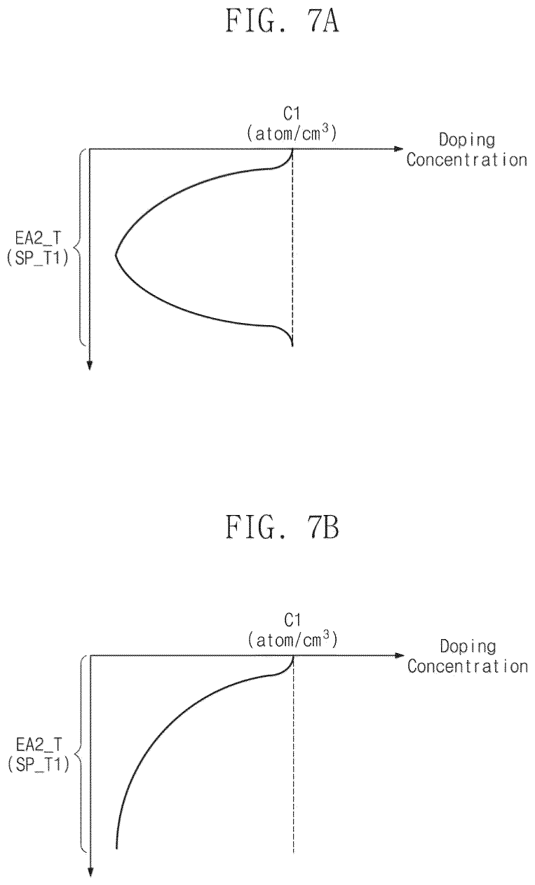

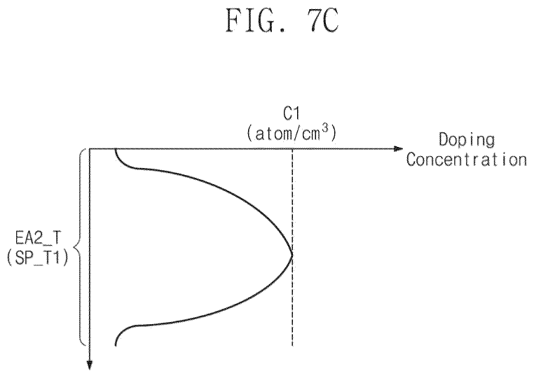

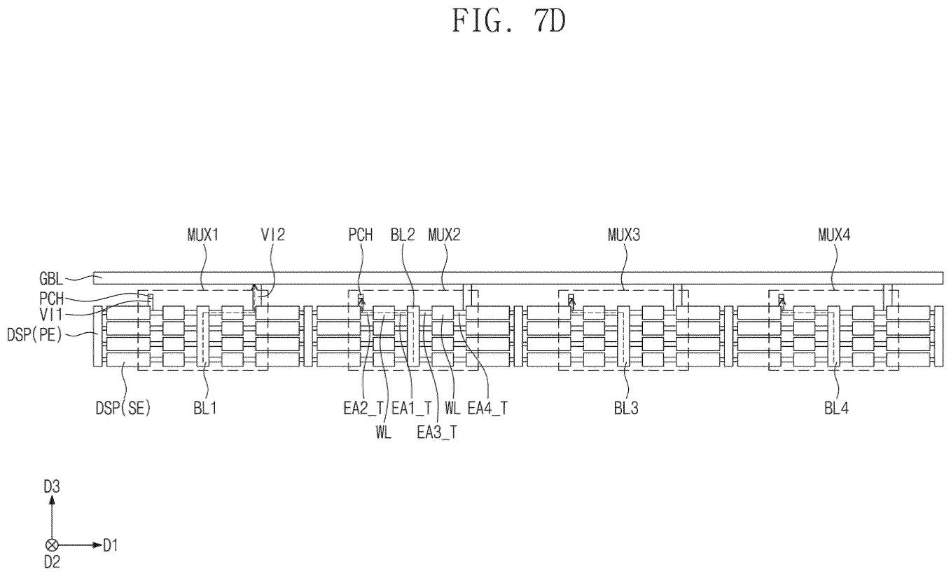

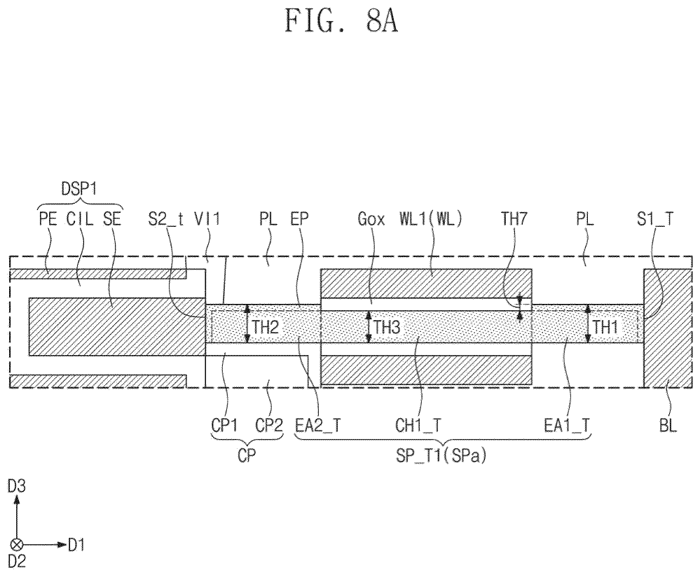

Hereinafter, various embodiments will be described with reference to FIGS. 6A to 7C. FIG. 6A is an enlarged view corresponding to a region ‘M’ of FIG. 5A. FIG. 6B is an enlarged view corresponding to a region ‘N’ of FIG. 5A. FIGS. 7A, 7B, and 7C are graphs illustrating doping concentrations through X-ray of FIG. 6A. The semiconductor pattern SP according to some embodiments will be described in more detail with reference to FIGS. 6A and 6B.

Referring to FIGS. 6A and 6B, the first semiconductor pattern SPa may include a first uppermost pattern SP_T1 which is a top pattern. The second semiconductor pattern SPb may include a second uppermost pattern SP_T2 which is a top pattern. The first and second uppermost patterns SP_T1 and SP_T1 may be semiconductor patterns that are furthest from an upper surface of the substrate 100 in the third direction D3. A bit line BL described below may be interposed between the first and second uppermost patterns SP_T1 and SP_T1.

The first uppermost pattern SP_T1 may include a first top edge portion EA1_T and a second top edge portion EA2_T spaced apart from each other, and a first top channel region CH1_T interposed therebetween. The first top channel region CH1_T may be surrounded by a first word line WL described below. The first top edge portion EA1_T and the second top edge portion EA2_T may not be surrounded by the first word line WL.

The first top edge portion EA1_T, the second top edge portion EA2_T, and the first top channel region CH1_T may be sequentially provided in an opposite direction to the first direction D1 (i.e., a-D1 direction). The first top edge portion EA1_T may be adjacent to a bit line BL described below. The first top edge portion EA1_T may be electrically connected to the bit line BL. The second top edge portion EA2_T may be adjacent to a first data storage pattern DSP1 described below. The second top edge portion EA2_T may be electrically connected to the first data storage pattern DSP1.

The first uppermost pattern SP_T1 may have a first top side surface S1_T and a second top side surface S2_T that face each other in the first direction D1. The first top side surface S1_T may be a side surface of the first top edge portion EA1_T, and the second top side surface S2_T may be a side surface of the second top edge portion EA2_T. The first top side surface S1_T may be adjacent to a bit line BL, and the second top side surface S2_T may be adjacent to a first data storage pattern DSP1. The bit line BL may be provided on the first top side surface S1_T, and the first data storage pattern DSP1 may be provided on the second top side surface S2_T.

A thickness TH1 of the first top edge portion EA1_T may be greater than a thickness TH3 of the first top channel region CH1_T. A thickness TH2 of the second top edge portion EA2_T may be greater than the thickness TH3 of the first top channel region CH1_T. An upper surface of the first top edge portion EA1_T and an upper surface of the second top edge portion EA2_T may be positioned at a higher level in the third direction D3 than an upper surface of the first top channel region CH1_T. A lower surface of the first top edge portion EA1_T and a lower surface of the second top edge portion EA2_T may be positioned at a lower level in the third direction D3 than a lower surface of the first top channel region CH1_T.

Referring back to FIG. 4, a width W1 of the first top edge portion EA1_T in the second direction D2 may be greater than a width W3 of the first top channel region CH1_T. A width W2 of the second top edge portion EA2_T in the second direction D2 may be greater than the width W3 of the first top channel region CH1_T.

Referring to FIGS. 6A and 7A to 7C, an upper surface and/or a lower surface of the first top edge portion EA1_T and the second top edge portion EA2_T may be doped. In some examples, side surfaces of the first and second top edges portions EA1_T and EA2_T may also be doped. An upper surface and/or a lower surface of each of the first top edge portion EA1_T and the second top edge portion EA2_T may include an n-type impurity. The first top edge portion EA1_T and the second top edge portion EA2_T may include a central portion between the upper surface and the lower surface. In FIGS. 7A to 7B, only an impurity concentration in the third direction D3 of the second top edge portion EA2_T is shown by way of example, but in each embodiment, the first top edge portion EA1_T may also have a doping concentration profile similar to FIGS. 7A to 7B.

Referring to FIG. 7A, a doping concentration of each of the first and second top edge portions EA1_T and EA2_T may be variously changed in the third direction D3 according to a doping concentration profile. For example, the doping concentration profile of each of the first and second top edge portions EA1_T and EA2_T may have a maximum doping concentration value C1 at each upper surface. The doping concentration of each of the first and second top edge portions EA1_T and EA2_T may decrease toward a central portion thereof in an X direction (opposite direction of D3) from the upper surface. The doping concentration of each of the first and second top edge portions EA1_T and EA2_T may increase again toward a lower surface in the X direction from the central portion.

Referring to FIG. 7B, the doping concentration profile of each of the first and second top edge portions EA1_T and EA2_T may have a maximum doping concentration value C1 at the upper surface and the doping concentration may decrease as a position moves away from the upper surface thereof. For example, the first and second top edge portions EA1_T and EA2_T may have a maximum doping concentration at the upper surface.

Referring to FIG. 7C, the doping concentrations of the first and second top edge portions EA1_T and EA2_T may have a maximum doping concentration value C1 at each of central portions thereof. The doping concentrations of the first and second top edge portions EA1_T and EA2_T may decrease as a position moves away from the central portions toward the upper and lower surfaces. The doped regions of the first and second top edge portions EA1_T and EA2_T may constitute source/drain regions of the transistor

The second uppermost pattern SP_T2 may include a third top edge portion EA3_T and a fourth top edge portion EA4_T spaced apart from each other, and a second top channel region CH2_T interposed therebetween. The second top channel region CH2_T may be surrounded by the second word line WL2. The third top edge portion EA3_T and the fourth top edge portion EA4_T may not be surrounded by the second word line WL2.

The third top edge portion EA3_T, the fourth top edge portion EA4_T, and the second top channel region CH2_T may be sequentially provided in the first direction D1. The third top edge portion EA3_T may be adjacent to a bit line BL described below. The third top edge portion EA3_T may be electrically connected to the bit line BL. The fourth top edge portion EA4_T may be adjacent to a second data storage pattern DSP2 described below. The fourth top edge portion EA4_T may be electrically connected to the second data storage pattern DSP2.

The second uppermost pattern SP_T2 may have a third top side surface S3_T and a fourth top side surface S4_T which face each other in the first direction D1. The third top side surface S3_T may be a side surface of the third top edge portion EA3_T, and the fourth top side surface S4_T may be a side surface of the fourth top edge portion EA4_T. The third top side surface S3_T may be adjacent to the bit line BL, and the fourth top side surface S4_T may be adjacent to the second data storage pattern DSP2. The bit line BL may be provided on the third top side surface S3_T, and the second data storage pattern DSP2 may be provided on the fourth top side surface S4_T.

A thickness TH4 of the third top edge portion EA3_T in the third direction D3 may be greater than a thickness TH6 of the second top channel region CH2_T. A thickness TH5 of the fourth top edge portion EA4_T in the third direction D3 may be greater than the thickness TH6 of the second top channel region CH2_T. An upper surface of the third top edge portion EA3_T and an upper surface of the fourth top edge portion EA4_T may be positioned at a higher level in the third direction D3 than and upper surface of the second top channel region CH2_T. A lower surface of the third top edge portion EA3_T and a lower surface of the fourth top edge portion EA4_T may be positioned at a lower level in the direction D3 than the lower surface of the second top channel region CH2_T.

Referring again to FIG. 4, a width W4 of the third top edge portion EA3_T in the second direction D2 may be greater than a width W6 of the second top channel region CH2_T. A width W5 of the fourth top edge portion EA4_T may be greater than the width W6 of the second top channel region CH2_T.

Referring again to FIGS. 6B and 7A to 7C, an upper surface and/or the lower surface of the third top edge portion EA3_T and the fourth top edge portion EA4_T may be doped. In some examples, side surfaces of the third and fourth top edges portions EA3_T and EA4_T may also be doped. For example, an upper surface and/or a lower surface of each of the third top edge portion EA3_T and the fourth top edge portion EA4_T may include an n-type impurity. The third top edge portion EA3_T and the fourth top edge portion EA4_T may include a central portion between the upper surface and the lower surface.

A doping concentration of each of the third and fourth top edge portions EA3_T and EA4_T may be variously changed in the third direction D3 according to a doping concentration profile. For example, the doping concentration profile of each of the third and fourth top edge portions EA3_T and EA4_T may have a doping concentration profile similar to a doping concentration profile of the second top edge portion EA2_T illustrated in FIG. 7A. For example, the doping concentration profile of each of the third and fourth top edge portions EA3_T and EA4_T may have a maximum doping concentration value at each of upper surfaces. The doping concentration of each of the third and fourth top edge portions EA3_T and EA4_T may decrease toward a central portion from the upper surface in the X direction (opposite direction of D3). The doping concentration of each of the third and fourth top edge portions EA3_T and EA4_T may increase again toward the lower surface from the central portion in the X direction.

In some examples, the doping concentration of each of the third and fourth top edge portions EA3_T and EA4_T may have a doping concentration profile similar to the concentration profile of the second top edge portion EA2_T as illustrated in FIG. 7B. Referring back to FIG. 7B, the doping concentration profile of each of the third and fourth top edge portions EA3_T and EA4_T may have a maximum doping concentration value C1 at the upper surface and the doping concentration may decrease as a position moves away from the upper surface. For example, the doping concentration of each of the third and fourth top edge portions EA3_T and EA4_T may be maximum doping concentration at the upper surface.

In some examples, the doping concentration of each of the third and fourth top edge portions EA3_T and EA4_T may have a doping concentration profile similar to the doping concentration profile of the second top edge portion EA2_T as illustrated in FIG. 7C. Referring back to FIG. 7C, the doping concentration profiles of the third and fourth top edge portions EA3_T and EA4_T may have a maximum doping concentration value C1 at each of the central portions thereof. The doping concentrations of the third and fourth top edge portions EA3_T and EA4_T may decrease as a position moves away from each of the central portions toward the upper and lower surfaces. The doped regions of the third and fourth top edge portions EA3_T and EA4_T may form source/drain regions of the transistor.

Referring back to FIGS. 3B, 5A, 6A, and 6B, one of the second top edge portion EA2_T and the fourth top edge portion EA4_T may be connected to a precharge line PCH, and the other may be connected to a global bit lines GBL. For example, the second top edge portion EA2_T may be connected to the precharge line PCH, and the fourth top edge portion EA4_T may be connected to the global bit lines GBL. The second top edge portion EA2_T and the precharge line PCH may be electrically connected through a first vertical via VI1. The fourth top edge portion EA4_T may be electrically connected to the global bit lines GBL through a second vertical via VI2. In one example, the first vertical via VI1 may be in contact with the upper surface of the second top edge portion EA2_T, and the second vertical via VI2 may be in contact with the upper surface of the fourth top edge portion EA4_T.

The precharge line PCH may serve to reset the cell between read/write operations of the three dimensional semiconductor device. The global bit lines GBL may be a high-level bit line that collectively processes data from the bit lines of a three dimensional semiconductor device. The precharge line PCH may extend in the second direction D2. The global bit lines GBL may be insulated from the precharge line PCH and extend in the first direction D1.

To access a specific memory cell, one bit line BL may be selected and the selected bit line BL may be connected to the global bit lines GBL and unselected bit lines may be connected to the precharge line PCH to disconnect the connection with the global bit lines GBL. In this case, a configuration that selectively connects each bit line BL to the precharge line PCH or the global bit lines GBL may be a MUX transistor. The MUX transistor may include a selection transistor and a keeper transistor. For example, the selection transistor may be a configuration that connects the selected bit line BL to the global bit lines GBL. The keeper transistor may be configured to connect the unselected bit lines to the precharge line PCH.

FIG. 7D is a drawing illustrating a plurality of MUX transistors of a three dimensional semiconductor device for illustrating an embodiment.

Referring to FIG. 7D, to access a memory cell including a first bit line BL1, the first bit line BL1 may be connected to the global bit lines GBL. Remaining second to fourth bit lines BL2, BL3, and BL4 may be connected to the precharge line PCH. In an embodiment, the first bit line BL1 may be connected to the global bit lines GBL by the third and fourth top edge portions EA3_T and EA4_T of the second uppermost patterns SP_T2. In an embodiment, the second to fourth bit lines BL2, BL3, and BL4 may be connected to the precharge line PCH by the first and second top edge portions EA1_T and EA2_T of the first uppermost patterns SP_T1, respectively.

According to various embodiments, the bit line BL may be selectively connected to the precharge line PCH or the global bit lines GBL by the first and second uppermost patterns SP_T1 and SP_T2. To this end, a doping process or a selective epitaxial growth (SEG) process may be performed on the edge portions of the first and second uppermost patterns SP_T1 and SP_T2. By utilizing the uppermost patterns that have been used as memory cells, electrical characteristics of the selection transistor and the keeper transistor of the MUX may be improved. In addition, loading capacitance of the bit line BL S/A may be reduced. As a result, reliability of the three dimensional semiconductor device may be improved.

A word line WL may surround first and second channel regions CH of a semiconductor pattern SP and extend in the second direction D2. For example, the word line WL may have a structure that completely surrounds the channel region CH of the semiconductor pattern SP (i.e., a gate all around structure). One word line WL may surround first and second channel regions CH1 and CH2 of each of the semiconductor patterns SP spaced apart from each other in the second direction D2. A plurality of word lines WL may be provided. Each of the word lines WL may surround the first and second channel regions CH1 and CH2 of a corresponding semiconductor pattern SP among the semiconductor patterns SP spaced apart from each other in the third direction D3 and may extend in the second direction D2. The word lines WL may be spaced apart from each other in the third direction D3.

The word line WL may include a first word line WL1 surrounding a first channel region CH1 of a first semiconductor pattern SPa in a first stacked structure ST1, and a second word line WL2 surrounding a second channel region CH2 of a second semiconductor pattern SPb in a second stacked structure ST2. The first word line WL1 and the second word line WL2 may be spaced apart from each other in a first direction D1.

The word line WL may include at least one of, but is not limited to, doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide or a conductive metal oxide (e.g., PtO, RuO₂, IrO₂, SrRuO₃ (SRO), (Ba,Sr)RuO₃ (BSRO), CaRuO₃ (CRO), LSCo). The word line WL may include a single layer or multiple layers of the above-mentioned materials. In some embodiments, the word line WL may include a two-dimensional semiconductor material, for example, the two-dimensional material may include graphene, a carbon nanotube, or a combination thereof.

A gate insulating layer Gox may be interposed between a word line WL and a semiconductor pattern SP. The gate insulating layer Gox may surround the semiconductor pattern SP. The word line WL may surround the channel region CH of the semiconductor pattern SP on the gate insulating layer Gox. A plurality of gate insulating layers Gox may be provided. Each of the gate insulating layers Gox may surround a corresponding semiconductor pattern SP.

The gate insulating layer Gox may include at least one of silicon oxide, silicon oxynitride, or a high-k dielectric material having a dielectric constant higher than that of silicon oxide. The high-k dielectric material may include a metal oxide or a metal oxynitride. For example, a high-k dielectric material usable as the gate insulating layer Gox may include at least one of HfO₂, HfSiO, HfSiON, HfTaO, HfTiO, HfZrO, ZrO₂, or Al₂O₃, but embodiments are not limited thereto. A material having a high-k dielectric is defined as a material having a higher dielectric constant than that of silicon oxide.

The gate insulating layer Gox may include a first top gate insulating layer surrounding the first top channel region CH1_T of the first uppermost pattern SP_T1 and a second top gate insulating layer surrounding the second top channel region CH2_T of the second uppermost pattern SP_T2. The first and second top gate insulating layers may include different materials from the other gate insulating layers Gox. For example, the first and second top gate insulating layers may include a high-k dielectric material, and the other gate insulating layers Gox may include a material having a lower dielectric constant than that of the first and second top gate insulating layers. In other words, dielectric constants of the first and second top gate insulating layers may be higher than those of the other gate insulating layers Gox.

Referring again to FIGS. 3 to 5B, a bit line BL may be provided between the first side surface S1 of the first semiconductor pattern SP and the third side surface S3 of the second semiconductor pattern SPb. The bit line BL may extend in the third direction D3 on the first side surface S1 of the first semiconductor pattern SPa. The bit line BL may extend in the third direction D3 on the third side surface S3 of the second semiconductor pattern SPb. Accordingly, one bit line BL may be in contact with the first side surface S1 and the third side surface S3 of each of the first semiconductor patterns SPa spaced apart from each other in the third direction D3. One bit line BL may be electrically connected to the first semiconductor patterns SPa and the second semiconductor patterns SPb. A plurality of bit lines BL may be provided. The bit lines BL may be spaced apart from each other in the second direction D2.

The bit lines BL may include, but are not limited to, at least one of doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide or a conductive metal oxide (e.g., PtO, RuO₂, IrO₂, SrRuO₃ (SRO), (Ba,Sr)RuO₃ (BSRO), CaRuO₃ (CRO), LSCo). The bit lines BL may include a single layer or multiple layers of the aforementioned materials. In some embodiments, the bit line BL may include a two-dimensional semiconductor material, for example, the two-dimensional material may include graphene, carbon nanotubes, or a combination thereof.

A data storage pattern DSP may be provided on a substrate 100. As illustrated in FIG. 4, the data storage pattern DSP may include a first data storage pattern DSP1 and a second data storage pattern DSP2. The first data storage pattern DSP1 may be in contact with a second side surface S2 of the first semiconductor pattern SPa and may be electrically connected to the first semiconductor pattern SPa. The second data storage pattern DSP2 may be in contact with a fourth side surface S4 of the second semiconductor pattern SPb and may be electrically connected to the second semiconductor pattern SPb. The first data storage pattern DSP1 and the second data storage pattern DSP2 may be spaced apart from each other in the first direction D1. The second side surface S2 and the fourth side surface S4 may be disposed in the first data storage pattern DSP1 and the second data storage pattern DSP2, respectively.

The data storage pattern DSP may include a storage electrode SE, a plate electrode PE, and a capacitor dielectric layer CIL interposed therebetween. For example, the three dimensional semiconductor device may be a dynamic random access memory (DRAM), and in this case, the data storage pattern DSP may be utilized as a capacitor. The storage electrode SE may be spaced apart from the plate electrode PE with the capacitor dielectric layer CIL interposed therebetween.

Each of the storage electrode SE and the plate electrode PE may include a conductive material. For example, the storage electrode SE and the plate electrode PE may each include at least one of doped silicon (Si), doped silicon germanium (SiGe), a metal material (e.g., Ti, Mo, W, Cu, Al, Ta, Ru, Ir, Co, Pt, Au, Ag, etc.), a metal nitride (e.g., nitrides including Ti, Mo, W, Cu, Al, Ta, Ru, Ir, Co, Pt, Au, Ag), titanium silicon nitride (e.g., TiSiN), titanium aluminum nitride (e.g., TiAlN), tantalum aluminum nitride (e.g., TaAlN)), a conductive oxide (e.g., PtO, RuO₂, IrO₂, SrRuO₃ (SRO), (Ba,Sr)RuO₃ (BSRO), CaRuO₃ (CRO), LSCo), or a metal silicide. Each of the storage electrode SE and the plate electrode PE may be a single layer made of a single material or a composite layer including two or more materials.

For example, the capacitor dielectric layer CIL may include at least one of a metal oxide such as HfO₂, ZrO₂, Al₂O₃, La₂O₃, Ta₂O₃, or TiO₂, or a dielectric material having a perovskite structure such as SrTiO₃ (STO), (Ba,Sr) TiO₃ (BST), BaTiO₃, PZT, or PLZT.

For another example, the data storage pattern DSP may be a variable resistance pattern that may be switched between two resistance states by an electrical pulse. In this case, the data storage pattern DSP may include a phase-change material, a perovskite compound, a transition metal oxide, a magnetic material, a ferromagnetic material, or an antiferromagnetic material whose crystal state changes depending on the amount of current.

The storage electrode SE may extend in the first direction D1 on the second side surface S2 of the first semiconductor pattern SPa. The storage electrode SE may extend in the opposite direction to the first direction D1 on the fourth side surface S4 of the second semiconductor pattern SPb. Although not shown in the drawings, a silicide pattern (not shown) may be provided between the storage electrode SE and the first semiconductor pattern SPa, and between the storage electrode SE and the second semiconductor pattern SPb. The silicide pattern may include a metal silicide (e.g., silicide including Ti, Mo, W, Cu, Al, Ta, Ru, Ir, Co). A plurality of storage electrode SE may be provided, and the storage electrodes SE may be spaced apart from each other in the third direction D3.

The plate electrode PE may include a portion extending in the third direction D3 and another portion protruding from the portion in the first direction D1 or in the opposite direction to the first direction D1. The another portion of the plate electrode PE may be interposed between the storage electrodes SE spaced apart in the third direction D3.

A buried insulating pattern 110 may be provided on the substrate 100. The buried insulating pattern 110 may cover a side surface of the cell array structure CS. The buried insulating pattern 110 may be interposed between the bit line BL and the word line WL, between the semiconductor patterns SP spaced apart from each other in the third direction D3, between the first edge portions EA1 spaced apart from each other in the second direction D2, between the third edge portions EA3 spaced apart from each other in the second direction D2, and between the word lines WL spaced apart from each other in the third direction D3. The buried insulating pattern 110 may cover the first edge portion EA1 and the third edge portion EA3. The buried insulating pattern 110 may include a single layer or composite layer including an insulating material.

A capping pattern CP may be provided in the cell array structure CS. The capping pattern CP may be interposed between the word lines WL and the data storage pattern DSP. The capping pattern CP may cover the second edge portion EA2 and the fourth edge portion EA4. The capping pattern CP may be interposed between the second edge portions EA2 spaced apart from each other in the third direction D3. The capping pattern CP may be interposed between the fourth edge portions EA4 spaced apart from each other in the third direction D3. The capping pattern CP may be interposed between the second edge portions EA2 of the first semiconductor patterns SPa spaced apart from each other in the second direction D2. The capping pattern CP may be interposed between the fourth edge portions EA4 of the second semiconductor patterns SPb spaced apart from each other in the second direction D2.

The capping pattern CP may include a first capping pattern CP1 surrounding a second edge portion EA2 of a semiconductor pattern SP and a second capping pattern CP2 on the first capping pattern CP1. The first capping pattern CP1 may conformally cover the second edge portion EA2, the fourth edge portion EA4, a side surface of the buried insulating pattern 110, a side surface of the word line WL, and a side surface of the gate insulating layer Gox. Each of the first capping pattern CP1 and the second capping pattern CP2 may include an insulating material. The second capping pattern CP2 may include a single layer or a composite layer.

A protective layer PL may be provided on the cell array structure CS. The protective layer PL may cover upper surfaces of the first stacked structure ST1, the second stacked structure ST2, and the data storage pattern DSP. The protective layer PL may include a single layer or a composite layer containing an insulating material. The protective layer PL may include a plurality of upper wirings (not shown). Some of the upper wirings may be electrically connected to the bit line BL, and others may be electrically connected to the data storage pattern DSP. In addition, although not shown in the drawings, word line pads (not shown) may be provided on a side surface of the cell array structure CS and may be electrically connected to the word lines WL.

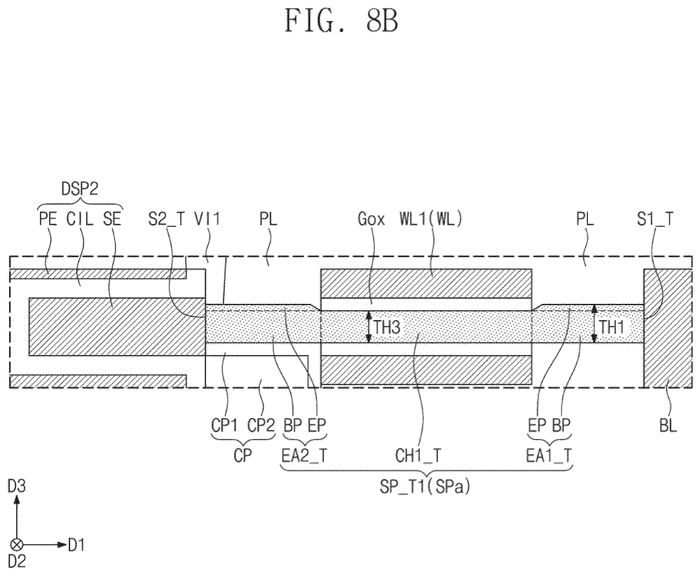

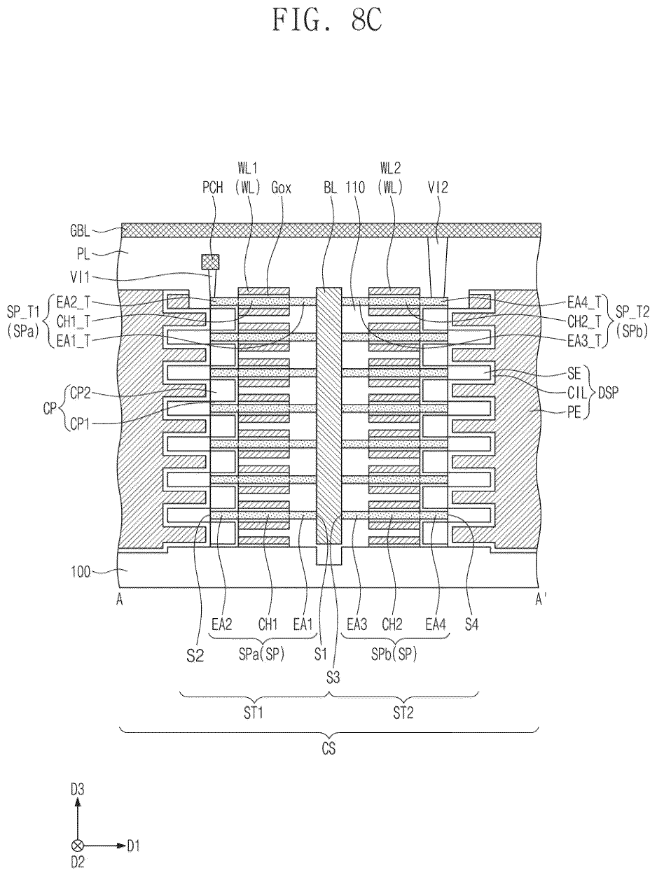

FIGS. 8A and 8B are enlarged views corresponding to region ‘M’ of FIG. 5A for illustrating some embodiments. Technical features overlapping with those described with reference to FIG. 6A are omitted for conciseness.

Referring to FIGS. 8A and 8B, upper and side surface portions of each of the first and second top edge portions EA1_T and EA2_T may include a growth pattern EP. The growth pattern EP may be provided between the first top edge portion EA1_T and the first data storage pattern DSP1 and between the second top edge portion EA2_T and the second data storage pattern DSP2. The growth pattern EP may be formed by a selective epitaxial growth (SEG) process. Specifically, the growth pattern EP may be formed by growing based on a silicon crystal of the first and second top edge portions EA1_T and EA2_T. The first and second top edge portions EA1_T and EA2_T may include a base pattern BP that serves as a growth base of the growth pattern EP. The growth pattern EP may be formed on an upper surface, a lower surface, and a side surface of the base pattern BP.

The growth pattern EP of the first and second top edge portions EA1_T and EA2_T may not be distinguished from the base pattern BP of the first and second top edge portions EA1_T and EA2_T. Due to the growth pattern EP, a thickness of the first and second top edge portions EA1_T and EA2_T may be greater than a thickness of the first top channel region CH1_T. A height difference between the upper surface of the first and second top edge portions EA1_T and EA2_T and the upper surface of the first top channel region CH1_T may be equal to the thickness of the growth pattern EP.

Referring to FIG. 8B, the growth pattern EP may be spaced apart from the word line WL. The growth pattern EP may be adjacent to the first top channel region CH1_T and may include a side surface. The side surface may be spaced apart from the word line WL and the gate insulating layer Gox in the first direction D1. The side surface may be an oblique side surface forming an acute angle with the first direction D1. As a result, a thickness of the first and second top edge portions EA1_T and EA2_T may gradually decrease as they get closer to the first top channel region CH1_T.

FIG. 8C is a cross-sectional view corresponding to the line A-A′ of FIG. 4 for illustrating some embodiments. Technical features overlapping with those described with reference to FIG. 5A are omitted for conciseness.

Referring to FIG. 8C, the first and second uppermost patterns SP_T1 and SP_T2 may not be connected to the first and second data storage patterns DSP1 and DSP2, respectively. Specifically, the second top edge portion EA2_T of the first uppermost pattern SP_T1 may be insulated from the first data storage pattern DSP1. The second top edge portion EA2_T may be spaced apart from the first data storage pattern DSP1 in the first direction D1. The protective layer PL may be interposed between the second top edge portion EA2_T and the first data storage pattern DSP1.

The fourth top edge portion EA4_T of the second uppermost pattern SP_T2 may be insulated from the second data storage pattern DSP2. The fourth top edge portion EA4_T may be spaced apart from the second data storage pattern DSP2 in the first direction D1. The protective layer PL may be interposed between the fourth top edge portion EA4_T and the second data storage pattern DSP2.

Therefore, the second top edge portion EA2_T of the first uppermost pattern SP_T1 may be connected only to a first vertical via VI1. The fourth top edge portion EA4_T of the second uppermost pattern SP_T2 may be connected only to a vertical second via VI2.

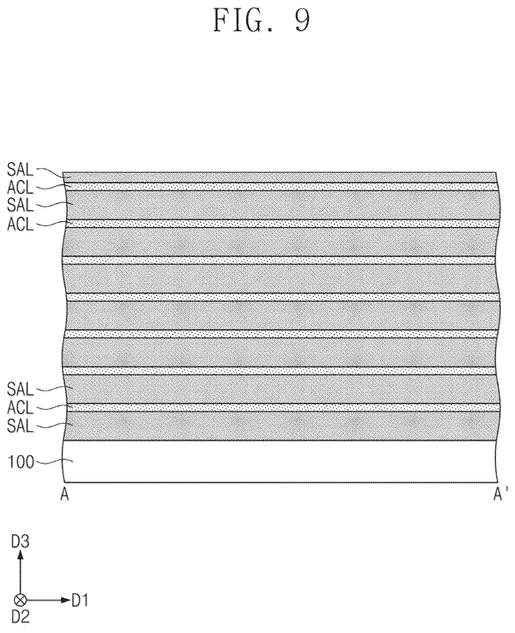

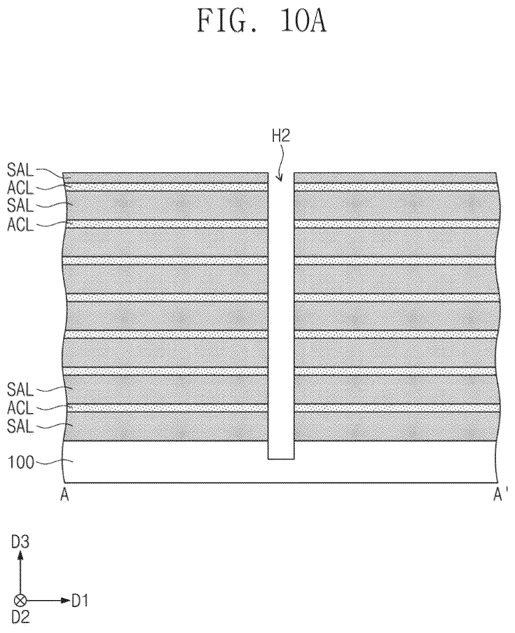

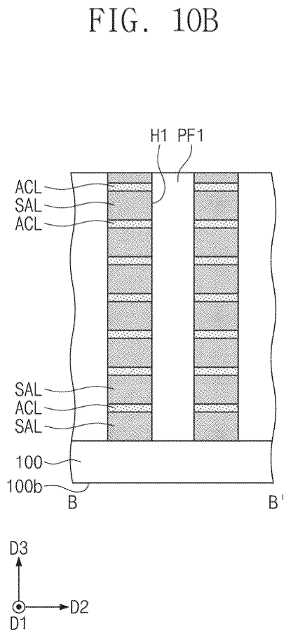

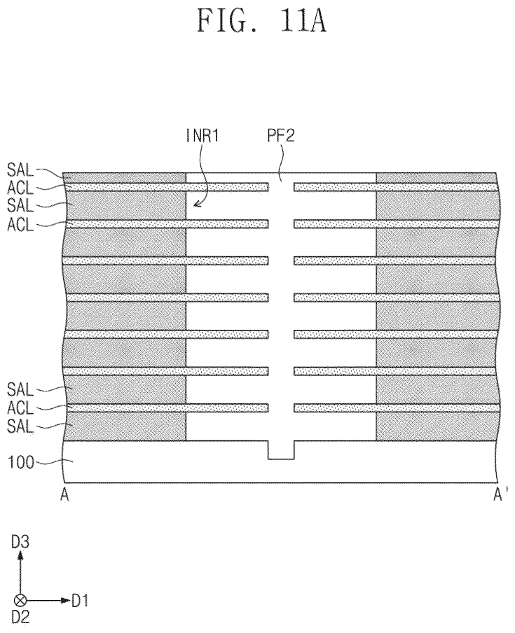

FIG. 9 to FIG. 18 are drawings illustrating a method of manufacturing a three dimensional semiconductor device according to some embodiments. In detail, FIGS. 9, 10A, 11A, 12, 13, 14A, 15A, 16, and 17 are cross-sectional views corresponding to line A-A′ of FIG. 4. FIGS. 10B, 11B, 14B, and 15B are cross-sectional views corresponding to line B-B′ of FIG. 4.

Referring to FIGS. 4 and 9, sacrificial layers SAL and active layers ACL may be alternately stacked on a substrate 100. Each of the sacrificial layers SAL and the active layers ACL may include a semiconductor material. The sacrificial layers SAL may include a material that has an etching selectivity with respect to the active layers ACL. Accordingly, when the sacrificial layers SAL are removed during the removal process described below, the active layers ACL may not be removed or may be removed to a small extent. For example, the active layers ACL may include one of silicon (Si), germanium (Ge), and silicon-germanium (SiGe), and the sacrificial layers SAL may include one of silicon (Si), germanium (Ge), and silicon-germanium (SiGe) other than the active layers ACL. According to some embodiments, the active layers ACL may include silicon (Si), and the sacrificial layers SAL may include silicon-germanium (SiGe). A thickness of the sacrificial layers SAL may be greater than a thickness of the active layers ACL. The sacrificial layers SAL may include a top sacrificial layer. The top sacrificial layer may have a thickness smaller than those of other sacrificial layers SAL.

Referring to FIGS. 10A and 10B, a portion of each of the sacrificial layers SAL and the active layers ACL may be removed to form first holes H1 on the substrate 100. The first holes H1 may extend in the first direction D1 and may be formed to be spaced apart from each other in the first and second directions D1 and D2. A portion of an upper surface of the substrate 100 may be exposed to the outside by the first holes H1. Through the above removal process, the sacrificial layers SAL and the active layers ACL may include regions extending elongatedly in the first direction D1 between the first holes H1 spaced apart from each other in the second direction D2, and regions extending elongatedly in the second direction D2 between the first holes H1 spaced apart from each other in the first direction D1.

The exposed portion of the upper surface of the substrate 100 may cover and fill the interior of the first holes H1 to form first preliminary filling patterns PF1. For example, the first preliminary filling pattern PF1 may include an insulating material. The first preliminary filling patterns PF1 may be formed to be spaced apart from each other in the first and second directions D1 and D2.

Some of the regions extending in the second direction D2 of the sacrificial layers SAL and the active layers ACL may be removed to form second holes H2 on the substrate 100. The second holes H2 may be formed to extend in the second direction D2. By the second holes H2, both side surfaces of the sacrificial layers SAL and the active layers ACL may be exposed to the outside. During the process of forming the second holes H2, a portion of the upper portion of the substrate 100 may be removed. By the second holes H2, a portion of the upper surface of the substrate 100 may be exposed to the outside.

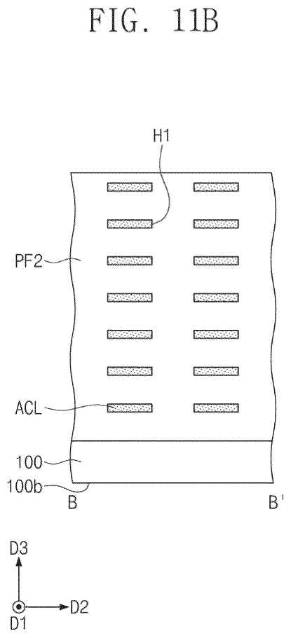

Referring to FIGS. 11A and 11B, both side surfaces of the sacrificial layers SAL that are exposed may be selectively removed through the second holes H2. Accordingly, first inner regions INR1 may be formed between the active layers ACL adjacent to the third direction D3. During the removal process, a portion of each of the first preliminary filling patterns PF1 may be removed together. Sidewalls of the first preliminary filling patterns PF1 may be aligned with sidewalls of the sacrificial layers SAL.

A second preliminary filling pattern PF2 may be formed to fill the first inner regions INR1, a region where a portion of the first preliminary filling patterns PF1 is removed, and interiors of the second holes H2. The second preliminary filling pattern PF2 may surround and cover the active layers ACL that do not vertically overlap the sacrificial layers SAL. The second preliminary filling pattern PF2 may include a single layer or composite layer including an insulating material. For example, the second preliminary filling pattern PF2 may include at least one of silicon oxide and silicon nitride.

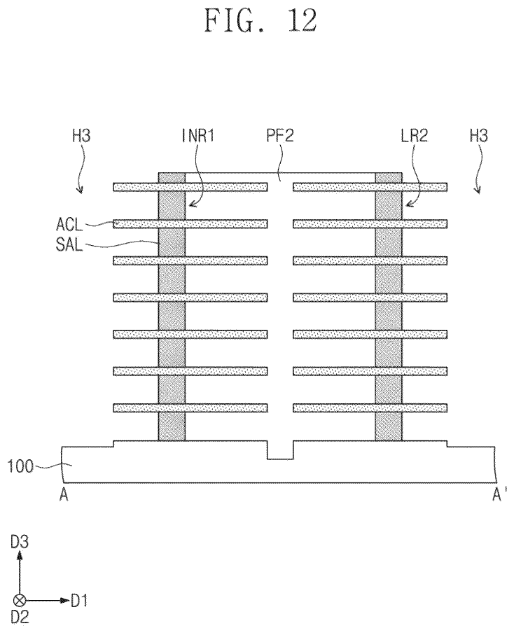

Referring to FIG. 12, a region extending in the second direction D2 among the sacrificial layers SAL and the active layers ACL may be removed to form a third hole H3 on a substrate 100. In a process of forming the third holes H3, one active layer ACL may be separated into semiconductor patterns SP adjacent to each other in the first direction D1. The semiconductor pattern SP may include a first semiconductor pattern SPa and a second semiconductor pattern SPb adjacent to each other in the first direction D1. In a process of forming the third holes H3, the sacrificial layers SAL may be exposed to the outside again.

Through the third holes H3, the exposed sacrificial layers SAL may be completely removed from the substrate 100. Accordingly, second inner regions INR2 may be formed between the second preliminary filling pattern PF2 and some regions of the active layers ACL that do not overlap. During the removal process, the first preliminary filling patterns PF1 may be completely removed from the substrate 100.

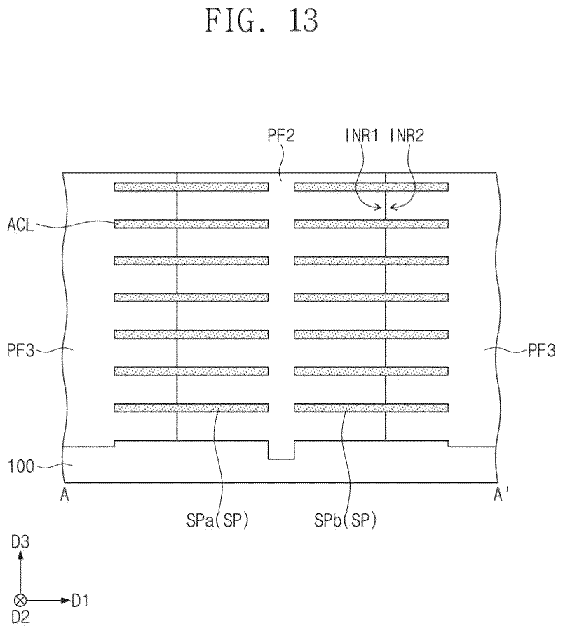

Referring to FIG. 13, a third preliminary filling pattern PF3 may be formed to fill the second inner regions INR2, a region from which the first preliminary filling patterns PF1 are removed, and an interior of the third holes H3. The third preliminary filling pattern PF3 may include a single layer or composite layer including an insulating material. For example, the third preliminary filling pattern PF3 may include at least one of silicon oxide and silicon nitride.

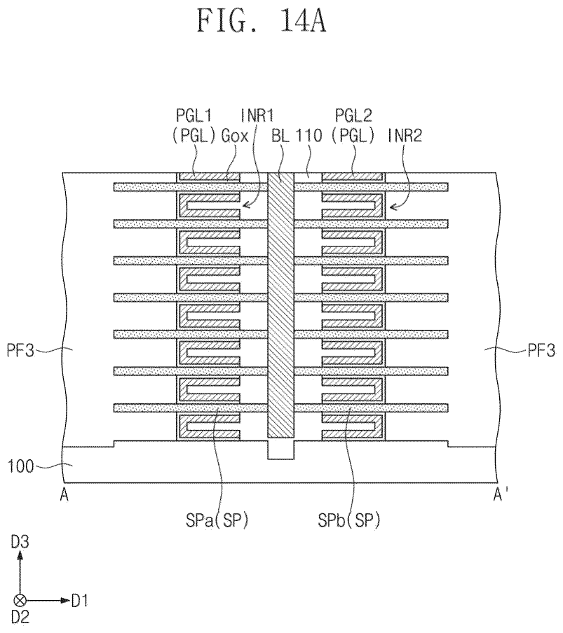

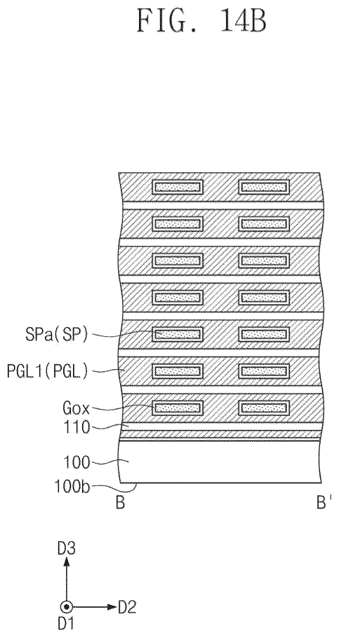

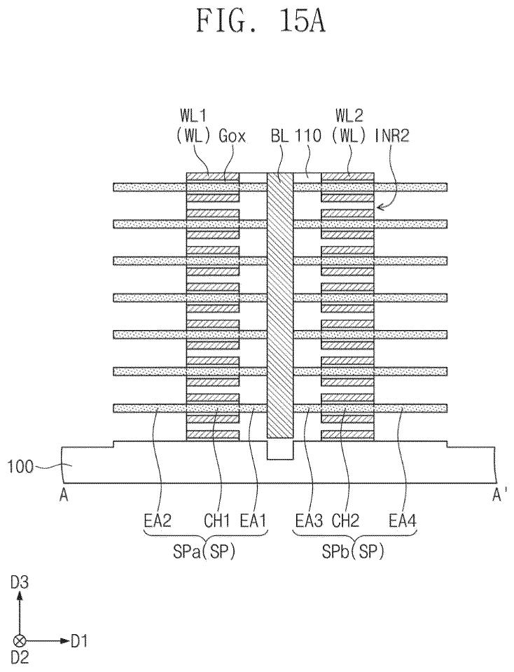

Referring to FIGS. 14A and 14B, the second preliminary filling pattern PF2 may be removed from the substrate 100. Thereafter, a gate insulating layer Gox and a preliminary gate conductive layer PGL1 and PGL2 may be formed in sequence in the first inner regions INR1. The gate insulating layer Gox and the preliminary gate conductive layer PGL1 and PGL2 may be formed to conformally cover a portion of the semiconductor pattern SP in sequence. The gate insulating layer Gox and the preliminary gate conductive layer PGL1 and PGL2 may be formed to surround and cover a portion of the semiconductor pattern SP. One gate insulating layer Gox and one preliminary gate conductive layer PGL1 and PGL2 may be formed to surround and cover a portion of each of the semiconductor patterns SP spaced apart from each other in the second and third directions D2 and D3. Thereafter, a buried insulating pattern 110 may be formed in a region from which the first inner regions INR1 and the second preliminary filling pattern PF2 are removed.

A bit line BL may be formed to penetrate the buried insulating pattern 110 and to be in contact with one side surface of the semiconductor patterns SP. The bit line BL may be in contact with the first semiconductor patterns SPa and the second semiconductor patterns SPb.

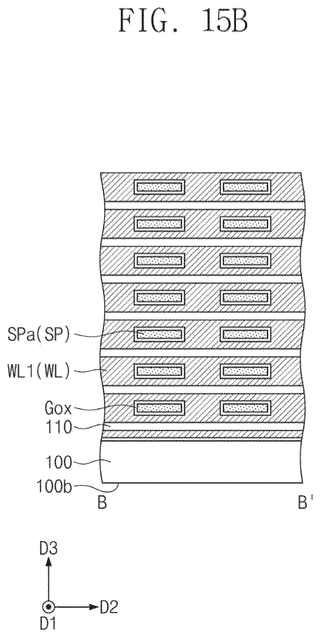

Referring to FIGS. 15A and 15B, the third preliminary filling pattern PF3 may be removed from the substrate 100. During the removal process, a portion of the gate insulating layer Gox and a portion of the preliminary gate conductive layers PGL1 and PGL2 may also be removed together. Accordingly, one gate insulating layer Gox may be separated into a plurality of gate insulating layers Gox spaced apart from each other in the second and third directions D2 and D3. One preliminary gate conductive layer PGL1 and PGL2 may be separated into a plurality of word lines WL1 and WL2 spaced apart from each other in the second and third directions D2 and D3. Each of the gate insulating layers Gox may surround a corresponding semiconductor pattern SP among the semiconductor patterns SP. Each of the word lines WL may surround a corresponding semiconductor pattern SP and a gate insulating layer Gox among the semiconductor patterns SP and the gate insulating layers Gox.

During the removal process, the second inner regions INR2 may be exposed to the outside. By the second inner regions INR2, one side surface of the word lines WL may be exposed to the outside.

The word lines WL may include first word lines WL1 surrounding the first semiconductor patterns SPa and second word lines WL2 surrounding the second semiconductor patterns SPb.

A region of the first semiconductor pattern SPa surrounded by the first word line WL1 may constitute a first channel region CH1 of the first semiconductor pattern SPa. A region of the second semiconductor pattern SPb surrounded by the second word line WL2 may constitute the second channel region CH2 of the second semiconductor pattern SPb.

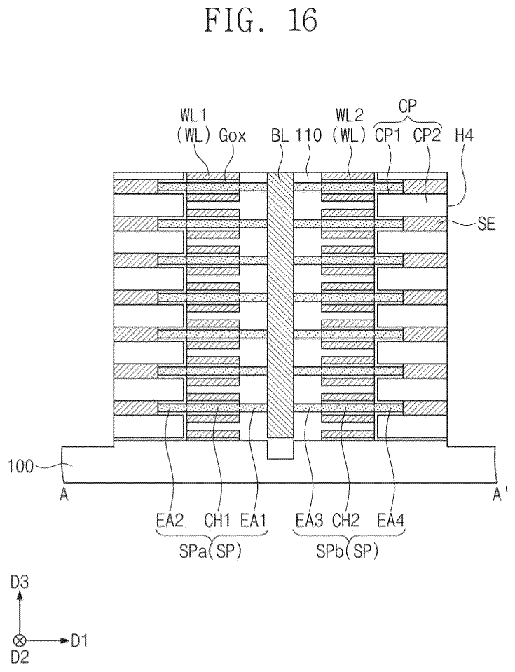

Referring to FIG. 16, the capping pattern CP may be formed to fill the region from which the second inner regions INR2 and the third preliminary filling pattern PF3 are removed. The capping pattern CP may include the first capping pattern CP1 and the second capping pattern CP2. The first capping pattern CP1 may conformally cover the second inner regions INR2, the second edge portions EA2 of the first semiconductor patterns SPa, and the fourth edge portions EA4 of the second semiconductor pattern SPb. The second capping pattern CP2 may fill the remainder of the second inner regions INR2 and surround the second edge portions EA2 of the first semiconductor patterns SPa and the fourth edge portions EA4 of the second semiconductor pattern SPb.

Thereafter, a portion of the capping pattern CP may be removed to form a fourth hole HLA on the substrate 100. The fourth hole HL4 may be formed to extend in the second direction D2. By the fourth hole HL4, the second edge portions EA2 of the first semiconductor patterns SPa and the fourth edge portions EA4 of the second semiconductor pattern SPb may be exposed to the outside.

Storage electrodes SE may be formed on the second edge portions EA2 of the first semiconductor patterns SPa and the fourth edge portions EA4 of the second semiconductor pattern SPb. For example, forming the storage electrodes SE may include forming silicide patterns (not shown) on the second edge portions EA2 of the first semiconductor patterns SPa and the fourth edge portions EA4 of the second semiconductor pattern SPb, and forming the storage electrodes SE through a SEG process using the silicide patterns as seeds.

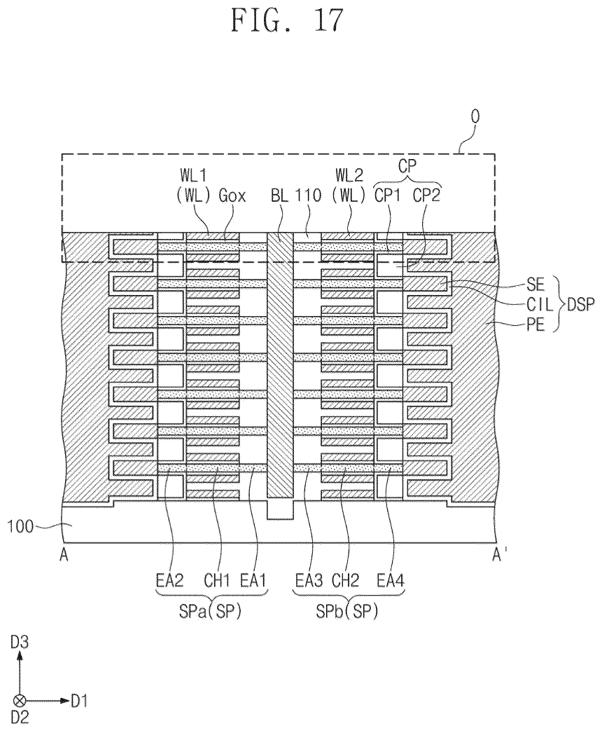

Referring to FIG. 17, a removal process may be performed on a portion of the second capping pattern CP2. Accordingly, a side surface of the second capping pattern CP2 may be aligned with a side surface of the second edge portions EA2 and a side surface of the fourth edge portions EA4. Thereafter, a capacitor dielectric layer CIL may be formed to conformally cover the storage electrodes SE. A plate electrode PE may be formed to fill a space between the storage electrodes SE, and a remainder of the fourth hole H4 of FIG. 16. The storage electrode SE, the capacitor dielectric layer CIL, and the plate electrode PE may constitute the first and second data storage patterns DSP1 and DSP2.

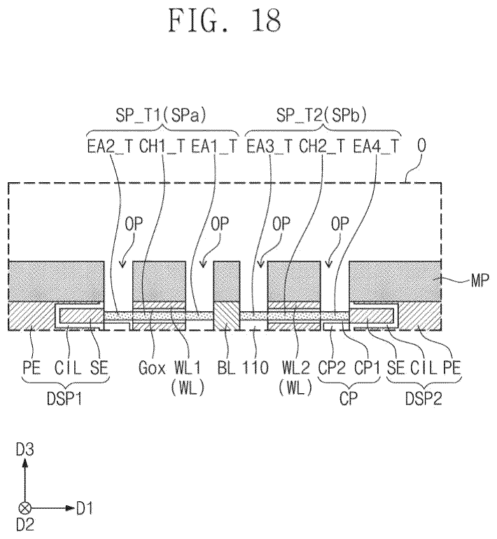

FIG. 18 is an enlarged view corresponding to region ‘O’ of FIG. 17. Referring to FIG. 18, a mask pattern MP may be formed on the first and second data storage patterns DSP1 and DSP2, the first and second word lines WL1 and WL2, and the bit line BL. The mask pattern MP may include a material having an etching selectivity with respect to the buried insulating pattern 110 and the capping patterns CP1 and CP2. The mask pattern MP may not cover the first and second top edge portions EA1_T and EA2_T of the first uppermost pattern SP_T1. The mask pattern MP may not cover the third and fourth top edge portions EA3_T and EA4_T of the second uppermost pattern SP_T2.

An etching process using the mask pattern MP as a mask may be performed to selectively remove the buried insulating pattern 110 and the capping pattern CP1 and CP2 on the first and second uppermost patterns SP_T1 and SP_T2. By the etching process, openings OP exposing the first to fourth top edge portions EA1_T, EA2_T, EA3_T, and EA4_T to the outside may be formed.

A doping process may be performed on the exposed first to fourth top edge portions EA1_T, EA2_T, EA3_T, and EA4_T. The doping process may include performing an ion implant process on the exposed first to fourth top edge portions EA1_T, EA2_T, EA3_T, and EA4_T. By performing the ion implant process, the doping concentration profile may be controlled on an upper surface, a lower surface, and a central portion of each of the first to fourth top edge portions EA1_T, EA2_T, EA3_T, and EA4_T. For example, the upper surface and lower surface of the first to fourth top edge portions EA1_T, EA2_T, EA3_T, and EA4_T may be doped. As another example, side surfaces of the first to fourth top edge portions EA1_T, EA2_T, EA3_T, and EA4_T may also be doped. The doping process may include doping the upper and lower surfaces of the first to fourth top edge portions EA1_T, EA2_T, EA3_T, and EA4_T with n-type impurities. By the doping, a vertical thickness and a width in the second direction D2 of the first to fourth top edge portions EA1_T, EA2_T, EA3_T, and EA4_T may increase.

As another example, a selective epitaxial growth (SEG) process may be performed on the exposed first to fourth top edge portions EA1_T, EA2_T, EA3_T, and EA4_T. The selective epitaxial growth (SEG) process may be performed on the exposed upper surfaces and the exposed side surfaces of the first to fourth top edge portions EA1_T, EA2_T, EA3_T, and EA4_T. Accordingly, a growth pattern EP may be formed on the upper and side surface portions of the first to fourth top edge portions EA1_T, EA2_T, EA3_T, and EA4_T. By the selective epitaxial growth process, a thickness and a width in the second direction D2 of the first to fourth top edge portions EA1_T, EA2_T, EA3_T, and EA4_T may be increased.

Thereafter, a protective layer PL may be formed to cover the cell array structure CS. A selective etching process may be performed on the protective layer PL to expose an upper surface of the first top edge portion EA1_T and an upper surface of the fourth top edge portion EA4_T. A conductive material may be disposed on the upper surface of the exposed first top edge portion EA1_T to form a first vertical via VI1 and a line providing a precharge line PCH. A conductive material may be disposed on the upper surface of the exposed fourth top edge portion EA4_T to form a second vertical via VI2 and a line providing a global bit lines GBL voltage.

According to various embodiments, uppermost semiconductor patterns may be used as Multiflexing (MUX) transistors. Specifically, the edge portions of the uppermost semiconductor patterns may have the thickness thicker than that of the channel region. This thickness may be because the edge portions are formed with n-type impurities or through the selective epitaxial growth (SEG) process. As a result, the precharge line and the global bit lines GBL may be selectively connected through the uppermost semiconductor patterns. In addition, the bit line selection transistor may be omitted, and the capacitance of the bit line may be reduced. As a result, the reliability of the three dimensional semiconductor device may be improved.

While various embodiments are described above, a person skilled in the art may understand that many modifications and variations are made without departing from the spirit and scope of the present disclosure defined in the following claims. Accordingly, the example embodiments should be considered in all respects as illustrative and not restrictive, with the spirit and scope of the present disclosure being indicated by the appended claims.

What is claimed is:

1. A three dimensional semiconductor device comprising:
a bit line that is spaced apart from a substrate and extends in a direction perpendicular to a lower surface of the substrate;
first semiconductor patterns on a first side surface of the bit line, the first semiconductor patterns including a first uppermost pattern which is an uppermost one of the first semiconductor patterns; and
a word line surrounding the first semiconductor patterns,
wherein the first uppermost pattern includes a first top edge portion that is spaced apart from a second top edge portion in a first direction, and a first top channel region between the first top edge portion and the second top edge portion,
wherein a thickness of the first top edge portion is greater than a thickness of the first top channel region, and
wherein a thickness of the second top edge portion is greater than the thickness of the first top channel region.

2. The three dimensional semiconductor device of claim 1, wherein a width of the first top edge portion in a second direction that is parallel to the lower surface of the substrate and perpendicular to the first direction is greater than a width of the first top channel region in the second direction, and
wherein a width of the second top edge portion in the second direction is greater than the width of the first top channel region in the second direction.

3. The three dimensional semiconductor device of claim 1, wherein an upper surface and a lower surface of the first top edge portion are doped and an upper surface and a lower surface of the second top edge portion are doped.

4. The three dimensional semiconductor device of claim 1, wherein an upper surface and a lower surface of the first top edge portion includes N-type impurities and an upper surface and a lower surface of the second top edge portion includes N-type impurities.

5. The three dimensional semiconductor device of claim 1, wherein each of the first top edge portion and the second top edge portion includes an upper surface, a lower surface, and a central portion between the upper surface and the lower surface,
wherein each of the first top edge portion and the second top edge portion has a doping concentration profile,
wherein the doping concentration profile of the first top edge portion has a maximum doping concentration on the upper surface of the first top edge portion, a doping concentration that decreases from the upper surface to the central portion of the first top edge portion, and a doping concentration that increases again from the central portion to the lower surface of the first top edge portion, and
wherein the doping concentration profile of the second top edge portion has a maximum doping concentration on the upper surface of the second top edge portion, a doping concentration that decreases from the upper surface to the central portion of the second top edge portion, and a doping concentration that increases again from the central portion to the lower surface of the second top edge portion.

6. The three dimensional semiconductor device of claim 1, wherein an upper portion and a lower portion of the first top edge portion are formed by a selective epitaxial growth (SEG) process, and an upper portion and a lower portion of the second top edge portion are formed by a SEG process.

7. The three dimensional semiconductor device of claim 1, wherein the first top edge portion includes a first side surface, and
wherein the second top edge portion includes a second side surface,
wherein the first side surface of the first top edge portion faces the second side surface of the second top edge portion in the first direction,
wherein the bit line is provided on the first side surface of the first top edge portion, and
wherein the three dimensional semiconductor device further includes a data storage pattern on the second side surface of the second top edge portion.

8. The three dimensional semiconductor device of claim 7, wherein the data storage pattern includes a storage electrode, a plate electrode, and a capacitor dielectric layer interposed between the storage electrode and the plate electrode.

9. The three dimensional semiconductor device of claim 1, further comprising second semiconductor patterns on a second side surface of the bit line, the second semiconductor patterns including a second uppermost pattern which is an uppermost one of the second semiconductor patterns,
wherein the second uppermost pattern includes a third top edge portion, a fourth top edge portion, and a second top channel region between the third top edge portion and the fourth top edge portion,
wherein a thickness of the third top edge portion is greater than a thickness of the second top channel region, and
wherein the thickness of the fourth top edge portion is greater than the thickness of the second top channel region.

10. The three dimensional semiconductor device of claim 9, wherein the third top edge portion includes a third side surface,
wherein the fourth top edge portion includes a fourth side surface,
wherein the third side surface of the third top edge portion faces the fourth side surface face of the fourth top edge portion in the first direction,
wherein the bit line is provided on the third side surface of the third top edge portion, and
wherein the three dimensional semiconductor device further includes a data storage pattern on the fourth side surface of the fourth top edge portion.

11. The three dimensional semiconductor device of claim 9, wherein one of the first top edge portion and the fourth top edge portion is connected to a precharge line, and the other one of the first top edge portion and the fourth top edge portion is connected to a global bit line.

12. A three dimensional semiconductor device comprising:
a bit line that is spaced apart from a substrate and extends in a direction perpendicular to a lower surface of the substrate;
first semiconductor patterns on a first side surface of the bit line, the first semiconductor patterns including a first uppermost pattern which is an uppermost one of the first semiconductor patterns;
second semiconductor patterns on a second side surface of the bit line, the second semiconductor patterns including a second uppermost pattern which is an uppermost one of the second semiconductor patterns; and
a word line surrounding the first semiconductor patterns and the second semiconductor patterns,
wherein the first uppermost pattern includes a first top edge portion, a first top channel region, and a second top edge portion in sequence in a first direction parallel to the lower surface of the substrate,
wherein the second uppermost pattern includes a third top edge portion, a second top channel region, and a fourth top edge portion in sequence in a direction opposite to the first direction,
wherein a thickness of the second top edge portion is greater than a thickness of the first top channel region,
wherein a thickness of the fourth top edge portion is greater than a thickness of the second top channel region, and
wherein one of the first top edge portion and the fourth top edge portion is connected to a precharge line, and the other one of the first top edge portion and the fourth top edge portion is connected to a global bit line.

13. The three dimensional semiconductor device of claim 12, wherein a width of the first top edge portion in a second direction that is parallel to the lower surface of the substrate and perpendicular to the first direction is greater than a width of the first top channel region in the second direction, and
wherein a width of the fourth top edge portion in the second direction is greater than a width of the second top channel region in the second direction.

14. The three dimensional semiconductor device of claim 12, wherein an upper surface and a lower surface of each of the first top edge portion, the second top edge portion, the third top edge portion, and the fourth top edge portion are doped.

15. The three dimensional semiconductor device of claim 12, wherein an upper surface and a lower surface of each of the first top edge portion, the second top edge portion, the third top edge portion, and the fourth top edge portion include N-type impurities.

16. The three dimensional semiconductor device of claim 12, wherein the first top edge portion includes a first side surface,
wherein the fourth top edge portion includes a second side surface,
wherein the first side surface of the first top edge portion is opposite to the second side surface of the fourth top edge portion in the first direction, and
wherein a three dimensional semiconductor device further includes a data storage pattern provided on each of the first side surface of the first top edge portion and the second side surface of the fourth top edge portion.

17. A three dimensional semiconductor device comprising:
a first stacked structure on a substrate and a second stacked structure adjacent to the first stacked structure in a first direction that is parallel to a lower surface of the substrate; and
a bit line between the first stacked structure and the second stacked structure,
wherein the first stacked structure includes:
first semiconductor patterns extending in the first direction on the substrate, the first semiconductor patterns including a first uppermost pattern which is an uppermost one of the first semiconductor patterns, the first uppermost pattern including a first top edge portion spaced apart from a second top edge portion in the first direction, and a first top channel region between the first top edge portion and the second top edge portion;
a first word line that surrounds the first top channel region and extends in a second direction that is parallel to the lower surface of the substrate and perpendicular to the first direction; and
a first data storage pattern on a side surface of the second top edge portion of the first uppermost pattern,
wherein the second stacked structure includes:
second semiconductor patterns extending in the first direction on the substrate, the second semiconductor patterns including a second uppermost pattern which is an uppermost one of the second semiconductor patterns, the second uppermost pattern including a third top edge portion, a fourth top edge portion, and a second top channel region between the third top edge portion and the third top edge portion;
a second word line that surrounds the second top channel region and extends in the second direction; and
a second data storage pattern on a side surface of the fourth top edge portion of the second uppermost pattern,
wherein a thickness of the first top edge portion and a thickness of the second top edge portion are greater than a thickness of the first top channel region, and
wherein a thickness of the third top edge portion and a thickness of the fourth top edge portion are greater than a thickness of the second top channel region.

18. The three dimensional semiconductor device of claim 17, wherein each of the first top edge portion, the second top edge portion, the third top edge portion, and the fourth top edge portion includes an upper surface, a lower surface, and a central portion between the upper surface and the lower surface,
wherein each of the first top edge portion, the second top edge portion, the third top edge portion, and the fourth top edge portion has a doping concentration profile, and
wherein the doping concentration profile of each of the first top edge portion, the second top edge portion, the third top edge portion, and the fourth top edge portion has a maximum doping concentration on the upper surface, a doping concentration that decreases from the upper surface to the central portion, and a doping concentration that increases again from the central portion to the lower surface.

19. The three dimensional semiconductor device of claim 17, wherein an upper portion and a lower portion of each of the first top edge portion, the second top edge portion, the third top edge portion, and the fourth top edge portion are formed by a selective epitaxial growth (SEG) process.

20. The three dimensional semiconductor device of claim 17, wherein one of the first top edge portion, the second top edge portion, the third top edge portion, and the fourth top edge portion is connected to a precharge line, and another one of the first top edge portion, the second top edge portion, the third top edge portion, and the fourth top edge portion is connected to a global bit line.
